(19) United States
(12) Patent Application Publication
(10) Pub. No.: US 2025/0070034 A1
(43) Pub. Date: Feb. 27, 2025

(54) INTEGRATED DEVICE WITH EMBEDDED INTERCONNECT STRUCTURE

(71) Applicant: QUALCOMM Incorporated, San Diego, CA (US)

(72) Inventors: Kuiwon KANG, San Diego, CA (US); Hong Bok WE, San Diego, CA (US); Michelle Yejin KIM, Carlsbad, CA (US)

(21) Appl. No.: 18/455,368

(22) Filed: Aug. 24, 2023

(51) Int. Cl. H01L 23/538; H01L 21/48; H01L 23/00; H01L 25/065

(52) U.S. Cl. CPC H01L 23/5386; H01L 21/4857; H01L 23/5383; H01L 24/16; H01L 24/17; H01L 24/81; H01L 25/0655; H01L 2224/16238; H01L 2224/1703; H01L 2224/81815

(57) ABSTRACT

A device includes a substrate including first conductors connecting contacts on a first side of the substrate to contacts on a second side of the substrate. The first conductors include metal lines arranged in metal layers separated from one another by dielectric layers and conductive vias interconnecting the metal lines. The substrate also includes second conductors connecting contacts on the first side of the substrate to contacts on the first side of the substrate to define conductive paths between a first die and a second die. The second conductors include metal lines arranged in metal layers that are separated from one another by dielectric layers and conductive vias interconnecting the metal lines of the second conductors. At least one metal layer of the second conductors is devoid of the metal lines of the first conductors.

### FIELD

Various features relate to integrated devices.

### BACKGROUND

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

State-of-the-art mobile application devices demand a small form factor, low cost, a tight power budget, and high electrical performance. Mobile package design has evolved to meet these divergent goals for enabling mobile applications that support multimedia enhancements. These mobile applications, however, are susceptible to power and signal routing issues when multiple dies are arranged within the small form factor. Design and manufacture of devices for use in mobile applications is challenging due to conflicts among the various design goals. For example, smaller form factor devices are generally more expensive to design and manufacture and small size can exacerbate other issues, such as heat management. As another example, performance can be increased by providing more signal paths between dies; however, providing more signal paths generally increases cost and size.

### SUMMARY

Various features relate to integrated devices.

One example provides a device that includes a substrate that includes first conductors electrically connecting first contacts on a first side of the substrate to second contacts on a second side of the substrate. The first conductors include a first set of metal lines arranged in a first set of metal layers separated from one another by a first set of dielectric layers. The first conductors also include a first set of conductive vias interconnecting the first set of metal lines vias through the first set of dielectric layers. The substrate also includes second conductors electrically connecting third contacts on the first side of the substrate to fourth contacts on the first side of the substrate to define conductive paths between a first die and a second die. The second conductors include a second set of metal lines arranged in a second set of metal layers that are separated from one another by a second set of dielectric layers. The second conductors also include a second set of conductive vias interconnecting the second set of metal lines. At least one metal layer of the second set of metal layers is devoid of metal lines of the first set of metal lines.

Another example provides a device that includes a first die comprising first circuitry, a second die comprising second circuitry, and a substrate. The substrate is configured to electrically connect the first circuitry to the second circuitry and to electrically connect the first circuitry, the second circuitry, or both, to one or more off-package devices. The substrate includes first conductors electrically connecting first contacts on a first side of the substrate to second contacts on a second side of the substrate. The first conductors include a first set of metal lines arranged in a first set of metal layers separated from one another by a first set of dielectric layers. The first conductors also include a first set of conductive vias interconnecting the first set of metal lines through the first set of dielectric layers. The substrate also includes second conductors electrically connecting third contacts on the first side of the substrate to fourth contacts on the first side of the substrate to define conductive paths between the first die and the second die. The second conductors include a second set of metal lines arranged in a second set of metal layers that are separated from one another by a second set of dielectric layers. The second conductors also include a second set of conductive vias interconnecting the second set of metal lines. At least one metal layer of the second set of metal layers is devoid of metal lines of the first set of metal lines.

Another example provides a method of fabrication of a device includes obtaining a first set of layers. The first set of layers includes a first set of metal layers separated from one another by a first set of dielectric layers, where the first set of metal layers define a first set of metal lines. The first set of layers also includes a first set of conductive vias through the first set of dielectric layers to interconnect the first set of metal lines. The method also includes forming an embedded interconnect structure on the first set of layers. The embedded interconnect structure includes a second set of metal layers defining a second set of metal lines, where at least one metal layer of the second set of metal layers is devoid of metal lines of the first set of metal lines. The embedded interconnect structure also includes a second set of dielectric layers including at least a bottom dielectric layer between the first set of metal layers and the second set of metal layers and a top dielectric layer on a top metal layer of the one or more second metal layers. The method further includes forming first pads and first conductive vias, where the first conductive vias extend through the embedded interconnect structure to the first set of metal layers. The method also includes forming first contacts on the first pads and second contacts that include via portions that extend through the top dielectric layer of the embedded interconnect structure to the top metal layer of the second set of metal layers.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a cross-sectional profile view of a device that includes an embedded interconnect structure.

FIG. 2 illustrates an exploded cross-sectional profile view of layers of a device that includes an embedded interconnect structure.

FIG. 3A, 3B, and 3C together illustrate an exemplary sequence for fabricating a device that includes an embedded interconnect structure.

FIG. 4 is a flowchart illustrating an exemplary method for fabricating a device that includes an embedded interconnect structure.

FIG. 5 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

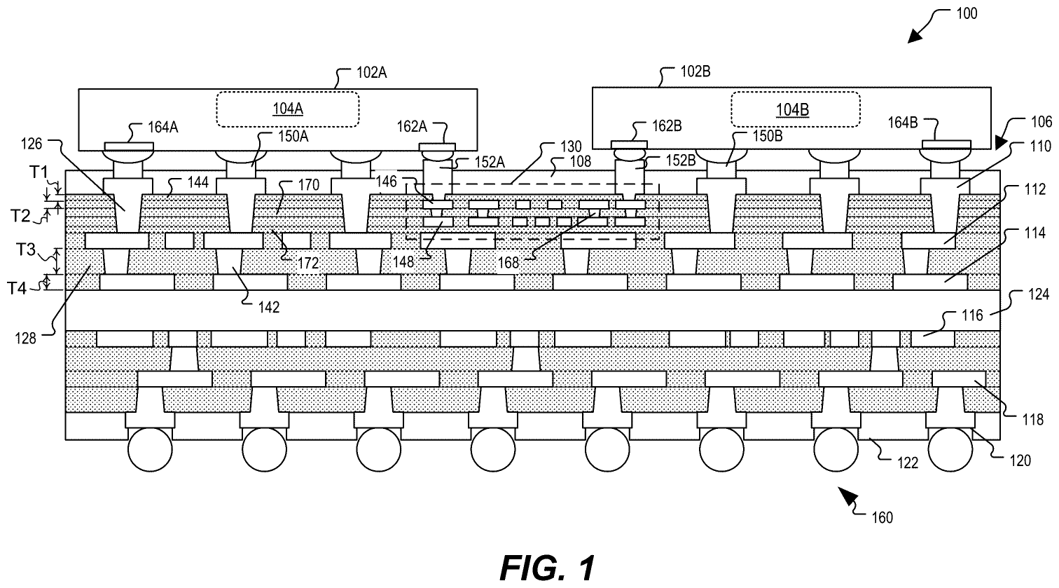

In some drawings, multiple instances of a particular type of feature are shown. In some circumstances, fewer than all of such features may be identified using a reference number. For example, a single reference number may be shown and associated with a representative instance of the feature so as not to obscure other aspects of the drawings. Where the physical and/or logical distinction between similar features is important, the same reference number may be used for each such feature, and the different instances may be distinguished by addition of a letter to the reference number. When the features as a group or a type are referred to herein (e.g., when no particular one of the features is being referenced), the reference number is used without a distinguishing letter. However, when one particular feature of multiple features of the same type is referred to herein, the reference number is used with the distinguishing letter. For example, referring to FIG. 1, multiple dies are illustrated and associated with reference numbers 102A and 102B. When referring to a particular one of these dies, such as a die 102A, the distinguishing letter “A” is used. However, when referring to any arbitrary one of these dies or to these dies as a group, the reference number 102 is used without a distinguishing letter.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

Improvements in manufacturing technology and demand for lower cost and more capable electronic devices has led to increasing complexity of integrated circuits (ICs). Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

State-of-the-art mobile application devices demand a small form factor, low cost, a tight power budget, and high electrical performance. Mobile package design has evolved to meet these divergent goals for enabling mobile applications that support multimedia enhancements. One approach to reducing package size is to integrate multiple dies within a single package. One example of a multi-die packages is a two-dimensional (2D) package architecture, in which two or more dies are coupled to a package substrate side-by-side with one another. Dies in this configuration can interact with one another (e.g., via die-to-die connections) and with off-package devices (e.g., via off-package connections). A challenge of such configurations is that die-to-die and off-package connections have different design criteria. For example, off-package connections are generally larger (e.g., in terms of line width, line spacing, etc.) than is needed for die-to-die connections. Various workarounds have been used to address this size difference. For example, additional devices (e.g., interposer devices or bridge die) can be added to a package to route die-to-die connections using smaller lines. As another example, additional layers or a separate stacked substrate can be added to the package substrate to provide die-to-die connection and redistribution routing to connect to off-package connections.

Another approach to reducing package size is a 2.5D architecture, in which two or more devices are positioned side-by-side with one another on the package substrate, and one or more additional devices are stacked on at least one of the side-by-side devices. To illustrate, a stacked die arrangement can be coupled to a package substrate side-by-side with another die, a passive device, another die stack, etc. Stacked die schemes and chiplet architectures are becoming more common as significant power performance area (PPA) yield enhancements are demonstrated for stacked die and chiplet architecture product lines.

Various aspects of the present disclosure provide a device that includes an embedded interconnect structure that addresses many of the challenges with multi-die packages. For example, the embedded interconnect structure is configured to provide signal paths between two or more dies coupled to a package substrate using a set of layers that are distinct from layers used to provide off-package connections. A technical benefit achieved by use of this arrangement is that a large number of die-to-die signal paths can be provided in a small region of the substrate, enabling increased performance due to increased interconnection between the dies without a corresponding increase in package size.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

### Exemplary Device Including an Embedded Interconnect Structure

FIG. 1 illustrates an example of a device 100 that includes multiple dies 102 coupled to a substrate 106. In FIG. 1, the dies 102 include a die 102A and a die 102B. Each die 102 can include circuitry 104, such as a plurality of transistors and/or other circuit elements arranged and interconnected to form a power distribution network (PDN), logic cells, memory cells, etc. Components of the circuitry 104 can be formed in and/or over a semiconductor substrate of the die 102. Different implementations can use different types of transistors, such as a field effect transistor (FET), planar FET, finFET, a gate all around FET, or mixtures of transistor types. In some implementations, a front end of line (FEOL) process may be used to fabricate the integrated circuitry 104 in and/or over the semiconductor substrate to form each of the dies 102.

The circuitry 104 of each die 102 is electrically connected to a set of contacts of the die 102. The contacts of the die 102A in FIG. 1 include contacts 162A that are configured to be electrically connected to contacts 162B of the die 102B and contacts 164A that are configured to be coupled, via the substrate 106, to off-package devices by way of contacts of the substrate 106 (e.g., a ball grid array (BGA) 160 in FIG. 1). Likewise, the contacts of the die 102B include contacts 162B that are configured to be electrically connected to the contacts 162A of the die 102A and contacts 164B that are configured to be coupled, via the substrate 106, to off-package devices by way of the contacts of the BGA 160. In a particular aspect, as described further below, die-to-die connections, such as signal paths between the contacts 162A and 162B are routed through an embedded interconnect structure within a die-to-die interconnect region 130 of the substrate 106.

The substrate 106 includes a stacked set of layers including metal layers and dielectric layers. Adjacent metal layers are separated from one another by one or more dielectric layers, and patterned to define metal lines. The metal lines are interconnected by conductive vias to define conductive paths through the substrate 106. In the specific example illustrated in FIG. 1, which is illustrative and not limiting, the substrate 106 includes a set of primary metal layers, including a metal layer 110 (e.g., an M1 layer), a metal layer 112 (e.g., an M2 layer), a metal layer 114 (e.g., an M3 layer), a metal layer 116 (e.g., an M4 layer), a metal layer 118 (e.g., an M5 layer), a metal layer 120 (e.g., an M6 layer), and a core 124. In FIG. 1, adjacent primary metal layers, such as the metal layer 114 and the metal layer 112, are separated by dielectric layers, such as a dielectric layer 128, and electrically connected through one or more conductive vias, such as a conductive via 142.

FIG. 1 also illustrates a solder resist layer 108 on a first side (e.g., a top side in the orientation illustrated in FIG. 1) of the substrate 106 defining openings through which the contacts 150 (e.g., contacts 150A and 150B) and 152 (e.g., contacts 152A and 152B) extend. Similarly, a solder resist layer 122 on a second side (e.g., a bottom side in the orientation illustrated in FIG. 1) of the substrate 106 defines openings to the metal layer 120 through which solder balls of the BGA 160 are coupled to the substrate 106.

A first set of conductors, including various metal lines among the primary metal layers 110, 112, 114, 116, 118, and 120 and conductive vias therebetween (e.g., the conductive via 142), form conductive paths between the BGA 160 and the contacts 164 of the dies 102. A second set of conductors, distinct from the first set of conductors, form conductive paths between the contacts 162. The second set of conductors includes various metal lines and conductive vias of the die-to-die interconnect region 130. For example, in FIG. 1, the second set of conductors includes metal lines defined within a metal layer 146, metal lines defined within a metal layer 148, and conductive vias 168 therebetween. The metal layers 146, 148 of the second set of conductors are referred to as “sub-layer metal layers” because the metal layers 146, 148 are disposed between an adjacent pair of the primary metal layers 110, 112, 114, 116, 118, and 120 of the substrate 106. To illustrate, in FIG. 1, the sub-layer metal layers 146, 148 are disposed between the metal layer 110 (e.g., the M1 layer) and the metal layer 112 (e.g., the M2 layer). In some implementations, the die-to-die interconnect region 130 can also include metal lines in the metal layer 110 (e.g., the M1 layer).

In FIG. 1, a dielectric layer 170 is disposed between the sub-layer metal layers 146, 148. Additionally, dielectric layers are disposed between the sub-layer metal layers 146, 148 and adjacent metal layers of the primary metal layers 110, 112, 114, 116, 118, and 120 of the substrate 106. For example, a dielectric layer 144 is disposed between an upper metal layer of the sub-layer metal layers (e.g., the metal layer 146) and the metal layer 110. As another example, a dielectric layer 172 is disposed between a lower metal layer of the sub-layer metal layers (e.g., the metal layer 148) and the metal layer 114.

The sub-layer metal layers 146, 148 are distinct from and do not overlap with (e.g., are disjoint from) the metal layers 110, 112, 114, 116, 118, and 120. For example, no metal line of the metal layers 110, 112, 114, 116, 118, and 120 is in the same layer as (e.g., coplanar with) any metal line of the sub-layer metal layers 146, 148. Thus, in implementations in which the die-to-die interconnect region 130 includes the sub-layer metal layers 146, 148 and does not include metal lines in the M1 layer (e.g., metal layer 110), the die-to-die region 130 is devoid of metal lines from the primary metal layers 110, 112, 114, 116, 118, and 120. That is, in such implementations, no metal line of any of the primary metal layers 110, 112, 114, 116, 118, and 120 traverses the die-to-die interconnect region 130.

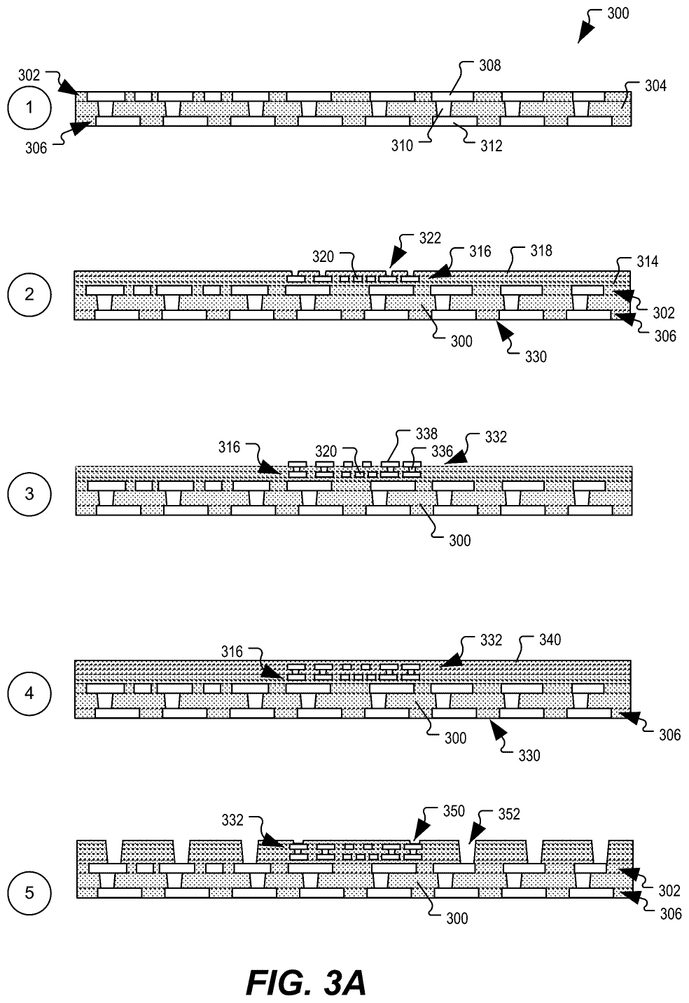

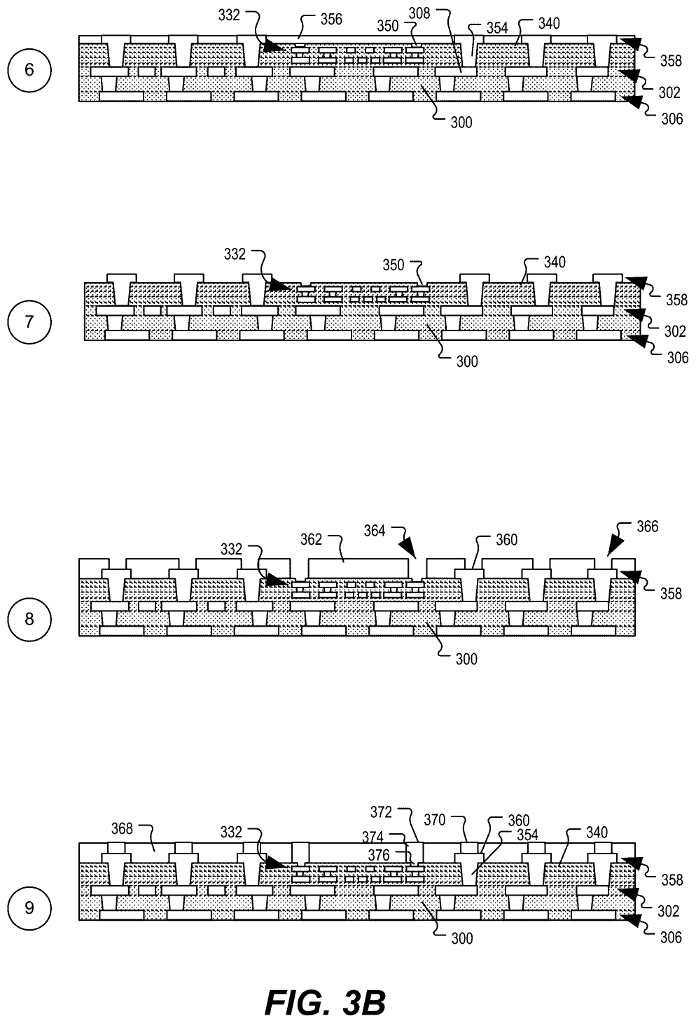

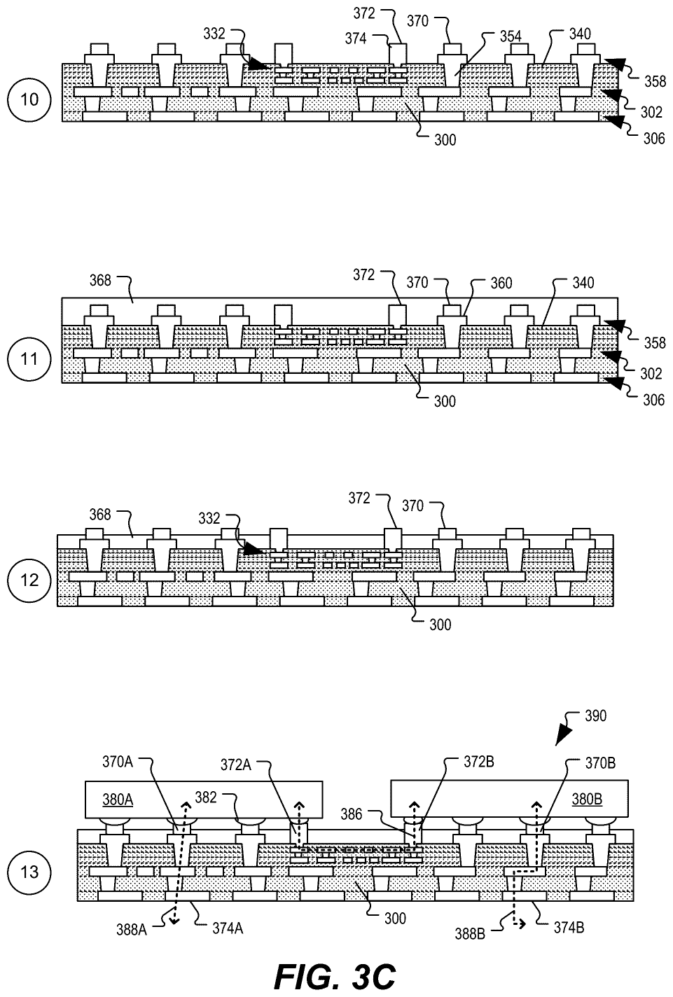

In FIG. 1, a post structure 126 includes a contact pad (on the metal layer 110) and a conductive via that extends from the metal layer 110 to the metal layer 112 through layers that form an embedded interconnect structure of the die-to-die interconnect region 130. As explained with reference to FIG. 3B, the post structure 126 can be formed as part of (e.g., at the same time as) the metal layer 110.

The primary metal layers 110, 112, 114, 116, 118, and 120 are sized and arranged to provide off-package connections, such as conductive paths for power, ground, and off-package input/output (I/O). For example, the metal lines of the primary metal layers 110, 112, 114, 116, 118, and 120 have first characteristic dimensions (e.g., line width, line spacing, and line thickness) selected to, among other things, provide target current carrying capacity and to enable use of standard manufacturing techniques. The sub-layer metal layers 146, 148 are sized and arranged to provide die-to-die connections. For example, the metal lines of the sub-layer metal layers 146, 148 have second characteristic dimensions (e.g., line width, line spacing, and line thickness) selected to, among other things, provide a large number of signal paths in a small area. In a particular aspect, the second characteristic dimensions are smaller than their counterparts among the first characteristic dimensions. For example, metal lines of the sub-layer metal layers 146, 148 have smaller line widths, smaller line thicknesses, and smaller line spacing than metal lines of the primary metal layers 110, 112, 114, 116, 118, and 120. To illustrate, in FIG. 1, the primary metal layers 110, 112, 114, 116, 118, and 120 have a characteristic layer thickness T4, and the sub-layer metal layers 146, 148 have a characteristic layer thickness T2, which is smaller than T4. Additionally, the dielectric layers 128 between adjacent metal layers of the primary metal layers 110, 112, 114, 116, 118, and 120 have a characteristic thickness that is greater than a characteristic thickness of the dielectric layers 144, 170, 172. To illustrate, in FIG. 1, the dielectric layer 128 has a thickness T3, and the dielectric layer 144 has a thickness T1, which is less than T3.

One technical benefit of the sub-layer metal layers 146, 148 having smaller characteristic dimensions than the primary metal layers 110, 112, 114, 116, 118, and 120 is that smaller metal lines enable routing of a larger number of signal paths between the dies 102 with little or no increase in the dimensions of the substrate 106. Increasing the number of signal paths between the dies 102 generally favors increase in performance of the device 100. Alternatively, as compared to a conventional device that routes die-to-die connections through the primary metal layers 110, 112, 114, 116, 118, and 120, the device 100 can route the same (or a greater) number of die-to-die connections through the sub-layer metal layers 146, 148 and thereby reduce the overall size of the device 100 relative to the conventional device.

Although FIG. 1 illustrates the die-to-die interconnect region 130 as disposed between the M1 and M2 layers (e.g., metal layers 110 and 112), in other examples, the die-to-die interconnect region 130 is disposed between a different adjacent pair of the primary metal layers 110, 112, 114, 116, 118, and 120. Further, although FIG. 1 illustrates a single die-to-die interconnect region 130, in other examples, the device 100 includes more than one die-to-die interconnect region 130. To illustrate, a third die (or another device) can be coupled to the substrate 106 and interconnected with either or both of the dies 102 via another die-to-die interconnect region disposed between the M1 and M2 layers or a different adjacent pair of the primary metal layers 110, 112, 114, 116, 118, and 120.

Although the region 130 is referred to herein as a die-to-die interconnect region 130, in other examples, the metal lines of the sub-layer metal layers 148, 148 and associated conductive vias 168 are used to interconnect other types of devices, such as to connect a die to a passive device or to connect two passive devices. Furthermore, although the die-to-die interconnect region 130 is illustrated in FIG. 1 as including two sub-layer metal layers 146, 148, in other examples, the die-to-die interconnect region 130 includes more than two or fewer than two metal layers. Likewise, although the substrate 106 is illustrated in FIG. 1 as including six primary metal layers 110, 112, 114, 116, 118, and 120, in other examples, the substrate 106 includes more than six or fewer than six primary metal layers.

In some implementations, the device 100 can be integrated with one or more other devices to form an integrated packaged device. For example, the substrate 106 can correspond to an upper substrate or a lower substrate of a package-on-package device. To illustrate, when the substrate 106 corresponds to a lower substrate of a package-on-package device, another substrate can be positioned over the dies 102 and electrically connected to the metal layer 110 via interposer conductors.

In some implementations, the dies 102 can correspond to chiplets which are interconnected via the die-to-die interconnect region 130. Alternatively, one of the dies 102 can be a bottom chiplet of a stacked chiplet arrangement. In such a stacked chiplet arrangement, another die (i.e., another chiplet) is stacked on top of and electrically connected to one of the dies. Using chiplets arranged and interconnected as a 3D stack can provide various benefits as compared to providing the same functional circuitry in one monolithic chip. For example, each chiplet is smaller than a monolithic die including all of the same functional circuit blocks would be. Since yield loss in IC manufacturing tends to increase as the die size increases, using smaller dies can reduce yield loss (i.e., increase yield) of the IC manufacturing process. Another benefit is that the chiplets can be fabricated in different locations and/or by different manufacturers, and in some cases, using different fabrication technologies (e.g., different fabrication technology nodes). As an example, one die 102 of a chiplet-based integrated device can include components (e.g., interconnects, transistors, etc.) that have a first minimum size, and another die of the chiplet-based integrated device can include components (e.g., interconnects, transistors, etc.) that have a second minimum size, where the second minimum size is greater than the first minimum size. In contrast, all of the circuitry of a monolithic die is fabricated using the same fabrication technologies and equipment. As a result, when manufacturing a monolithic die, the entire die may be subject to the tightest manufacturing constraint of the most complex component of the monolithic die. In contrast, when using chiplets, different chiplets can be manufactured using different fabrication technologies (e.g., different fabrication technology nodes), and only the chiplet or chiplets that include the most complex components are subjected to the tightest manufacturing constraints. In this arrangement, chiplets fabricated using less expensive and/or higher yield fabrication technologies can be integrated with chiplets fabricated using more expensive and/or lower yield fabrication technologies to form an integrated device, resulting in overall savings. Still further, in some cases, as technology improves, the design of one or both of the chiplets can be changed such that new chiplet design is integrated with an older chiplet design, which improves manufacturing flexibility and reduces design costs.

In various implementations, the device 100 can include components such as a power management integrated circuit (PMIC), an application processor (including one or more processor cores), a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory (including multiple memory cells), power management processor, and/or combinations thereof. In such implementations, the dies 102 can operate as any of these components (or a combination of these components) that includes active circuitry.

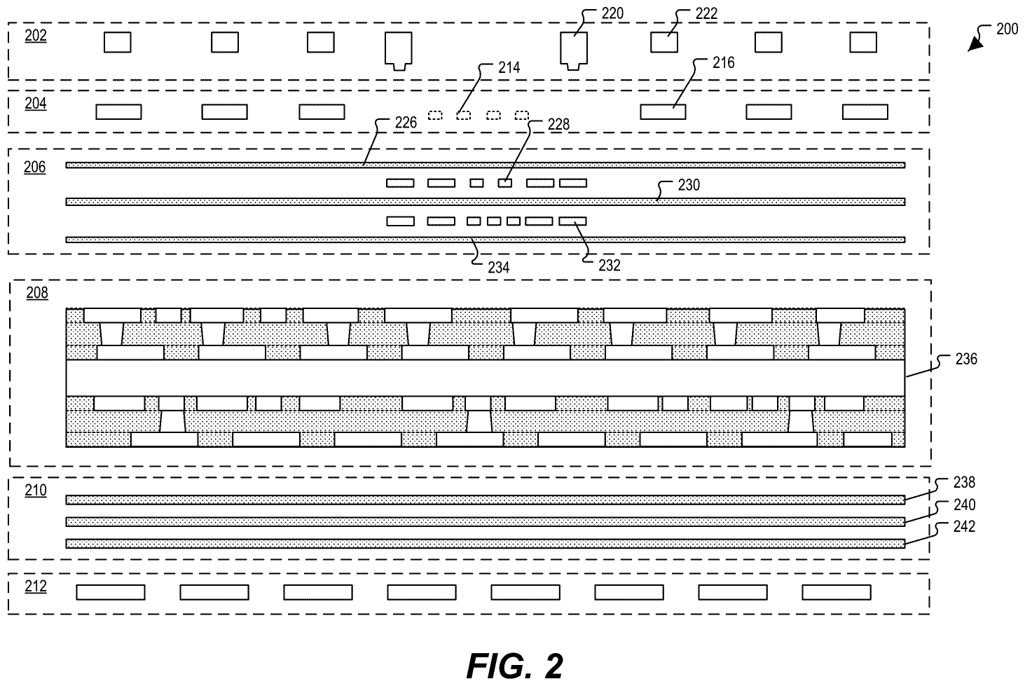

FIG. 2 illustrates an exploded cross-sectional profile view of layers 200 of a device that includes an embedded interconnect structure, such as the device 100 of FIG. 1. The layers 200 illustrated in FIG. 2 follow the same general arrangement as the layers of the device 100 described with reference to FIG. 1.

In FIG. 2, the layers 200 include a contact layer 202 that includes contacts 220 associated with a die-to-die interconnect region (e.g., the die-to-die interconnect region 130 of FIG. 1) and contacts 222 associated with primary metal layers. For example, the contacts 220 can correspond to the contacts 152 of FIG. 1, which are configured to electrically connect the contacts 162 of the dies 102 to the sub-layer metal layer 146 of the die-to-die interconnect region 130. In this example, the contacts 222 can correspond to the contacts 150 of FIG. 1, which are configured to electrically connect the contacts 164 of the dies 102 to the M1 layer (e.g., the metal layer 110).

The layers 200 also include an M1 layer 204, which in a particular example, corresponds to the metal layer 110 of the substrate 106 of FIG. 1. As illustrated in FIG. 2, the M1 layer 204 includes contact pads 216 for the contacts 222, and can optionally include metal lines 214 of the die-to-die interconnect region, metal lines associated with the primary metal layers, or both.

The layers 200 also include a set of layers 206 defining a set of sub-layer conductors of a die-to-die interconnect region (e.g., the die-to-die interconnect region 130 of FIG. 1). In FIG. 2, the set of layers 206 includes a dielectric layer 226, a metal layer 228, a dielectric layer 230, a metal layer 232, and a dielectric layer 234. In a particular example, the dielectric layer 226 corresponds to the dielectric layer 144 of FIG. 1, the metal layer 228 corresponds to the sub-layer metal layer 146 of FIG. 1, the dielectric layer 230 corresponds to the dielectric layer 170 of FIG. 1, the metal layer 232 corresponds to the sub-layer metal layer 148 of FIG. 1, and the dielectric layer 234 corresponds to the dielectric layer 172 of FIG. 1. The metal layers 228 and 232 of the set of layers 206 define metal lines, which can be interconnected by conductive vias (e.g., the conductive vias 168 of FIG. 1) to define conductive paths between two or more of the contacts 220. Although two metal layers 228, 232 are illustrated in FIG. 2, the set of layers 206 can include more than two or fewer than two metal layers.

The layers 200 also include another set of layers 208 defining a set of conductors of primary metal layers. For example, the set of layers 208 can correspond to or include the primary metal layers 112, 114, 116, and 118 (e.g., the M2-M5 layers) of the substrate 106 of FIG. 1 and dielectric layers therebetween (e.g., the dielectric layer 128). In FIG. 2, the set of layers 208 is illustrated as including an optional core 236, which can be omitted in some implementations.

The layers 200 also include a set of dielectric layers 210, including a dielectric layer 238, a dielectric layer 240, and a dielectric layer 242. In a particular implementation, the set of dielectric layers 210 corresponds to or includes a dielectric layer between the bottom two metal layers of a substrate (e.g., the primary metal layers 118 and 120 of the substrate 106 of FIG. 1). In a particular implementation, each of the dielectric layers 238, 240, 242 is formed or applied to a stack of layers at the same time as a corresponding one of the dielectric layers 226, 230, 234. For example, the dielectric layers 226, 230, 234 and the dielectric layers 238, 240, 242 can be applied in pairs using a symmetric lamination process. In this example, the dielectric layer 234 and the dielectric layer 238 are applied to the set of layers 208 to form a first working stack of layers. Subsequently, the metal layer 232 is formed on the first working stack of layers, and the dielectric layer 230 and the dielectric layer 240 are applied to form a second working stack of layers. After this one or more additional metal layers and pairs of dielectric layers can be formed on the second working stack of layers (depending on the specific number of layers desired to form a die-to-die interconnect region). To illustrate, the metal layer 228 can be formed on the second working stack of layers, and the dielectric layers 226 and 242 can be applied to form a third working stack of layers. A technical benefit of forming the dielectric layers 226, 230, 234 and the dielectric layers 238, 240, 242 using a symmetric lamination process is that symmetric lamination can reduce unbalanced stresses within a substrate (e.g., the substrate 106 of FIG. 1), which can reduce substrate warpage.

Additional primary metal layers can be formed on the third working stack of layers. To illustrate, in the example illustrated in FIG. 2, the M1 layer 204 and an M6 layer 212 can be formed on the third working stack of layers. Thus, in this example, the set of dielectric layers 210 can be considered to replace one of the dielectric layers separating a pair of primary metal layers.

Although the layers 200 illustrated in FIG. 2 represent a stacked layer arrangement that can result when a symmetric lamination process is used, in other implementations, the device 100 of FIG. 1 can be formed without using a symmetric lamination process, in which case the set of dielectric layers 210 can be replaced by a single dielectric layer having appropriate characteristic dimensions associated with the primary metal layers (e.g., having approximately the layer thickness T3 of FIG. 1, which is greater than the layer thickness of each of the dielectric layers 226, 230, 234, 238, 240, and 242).

### Exemplary Sequence for Fabricating a Device Including an Embedded Interconnect Structure

In some implementations, fabricating a device that includes an embedded interconnect structure includes several processes. FIGS. 3A, 3B, and 3C illustrate an exemplary sequence for providing or fabricating a device that includes an embedded interconnect structure, as described with reference to FIG. 1 or FIG. 2. In some implementations, the sequence of FIGS. 3A-3C may be used to provide (e.g., during fabrication of) the device 100 of FIG. 1 or another device that includes the layers 200 of FIG. 2.

It should be noted that the sequence of FIGS. 3A-3C may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 3A-3C.

Stage 1 of FIG. 3A illustrates a state after formation of a set of primary metal layers 300 of a substrate. A simplified set of primary metal layers 300 is illustrated in FIGS. 3A-3C (relative to FIGS. 1 and 2) and includes a metal layer 302 and a metal layer 306 in or on a dielectric layer 304. The metal layers 302 and 306 are patterned to form conductive lines, such as a metal line 308 of the metal layer 302 and a metal line 312 of the metal layer 306. Conductive vias interconnect various ones of the metal lines. For example, a conductive via 310 through the dielectric layer 304 electrically connects the metal line 308 and the metal line 312. The set of primary metal layers 300 can be formed using a lamination process. For example, the metal layers 302 and 306 can be formed concurrently on the dielectric layer 304 using a symmetric lamination process. Alternatively, the set of primary metal layers 300 can be built up on a carrier substrate (not shown) or a core (e.g., the core 236 of FIG. 2) of the substrate. To illustrate, the primary metal layers 300 can correspond to or include the set of layers 208 of FIG. 2, in which case the primary metal layers 300 can be formed on the core 236 using a symmetric lamination process.

The metal layers 302 and 306 can be patterned to define the metal lines (e.g., the metal lines 308, 312) using one or more subtractive processes (such as etching, engraving, or ablation of material of a metal layer), using one or more additive processes (such as printing or deposition), or using a combination of additive and subtractive processes. The additive or subtractive processes can use patterned mask layers, such as patterned dry films, to guide patterning of the metal layers 302, 306 to define the metal lines. The dielectric layer 304 can correspond to a polymer layer or a pre-preg layer that is cured to form the dielectric layer 304. The conductive vias can be formed using drilling operations to form openings, which are subsequently filled or coated with a conductive material (e.g., using a plating or deposition process) to form the conductive vias. In some implementations, plating or deposition guided by a mask layer can be used to concurrently form a metal layer and to fill an opening to form a conductive via.

The specific set of primary metal layers 300 illustrated in FIG. 3A is merely one example. In other implementations, Stage 1 ends with obtaining any type or configuration of package substrate that includes conductors (e.g., two or more metal layers and conductive vias therebetween) that form conductive paths between two sides of the set of primary metal layers 300. For example, in some implementations, the set of primary metal layers 300 includes or corresponds to the set of layers 208 of FIG. 2 or another substrate that includes contacts on each side and conductors defining conductive paths therebetween.

Stage 2 illustrates a state after formation of a first portion of a set of sub-layer metal layers on the set of primary metal layers 300. The first portion of a set of sub-layer metal layers includes a dielectric layer 314 on the metal layer 302, a metal layer 316 on the dielectric layer 314, and a dielectric layer 318 on the metal layer 316. At Stage 2, the metal layer 316 has been patterned (e.g., using one or more subtractive processes, one or more additive processes, or a combination of additive and subtractive processes) to define metal lines, such as a metal line 320. Additionally, at Stage 2, the dielectric layer 318 has been patterned (e.g., using one or more subtractive processes, one or more additive processes, or a combination of additive and subtractive processes) to form openings, such as an opening 322, through the dielectric layer 318 to the metal layer 316.

The metal layer 316 is thinner than each of the metal layers 302 and 306 of the set of primary metal layers 300. Additionally, or alternatively, the metal lines of the set of sub-layer metal layers (e.g., the metal line 320) are more closely packed (e.g., have smaller line width, smaller pitch, or both) than the metal lines of the set of primary metal layers 300 (e.g., the metal lines 308, 312). Further, in some cases, the dielectric layers 318, 314 are thinner than the dielectric layer 304.

In the example illustrated in FIG. 3A, the dielectric layers 314, 318 are shown as applied to only one side of the set of primary metal layers 300. For example, the metal layer 306 remains exposed on a side 330 of the set of primary metal layers 300. Optionally, in some implementations, a symmetric lamination process is used to apply the dielectric layers 314, 318 of the set of sub-layer metal layers. In such implementations, additional dielectric layers are coupled to the set of primary metal layers 300 on the side 330, as described with reference to the set of dielectric layers 210 of FIG. 2.

Stage 3 illustrates a state after formation of a second portion of the set of sub-layer metal layers. The second portion of the set of sub-layer metal layers includes conductive vias (such as a conductive via 336) and a metal layer 332. The conductive vias are formed within the openings in the dielectric layer 318 (e.g., the opening 322) and electrically connected to one or more metal lines of the metal layer 316. For example, the conductive vias can be formed using one or more plating or deposition operations.

In some implementations, the metal layer 332 is formed and patterned concurrently with formation of the conductive vias. For example, a patterned film can be applied to the dielectric layer 318 to define openings for the metal lines (e.g., metal line 338) of the metal layer 332 and the conductive vias (e.g., the conductive via 336). In this example, the metal layer 332 and the conductive vias can be formed using a plating or deposition process guided by the patterned film. The metal lines of the metal layer 332 are interconnected with appropriate metal lines of the metal layer 316 through the conductive vias to form signal paths.

In the example illustrated in FIGS. 3A-3C, the metal layer 332 is a top layer of the set of sub-layer metal layers; hence, an embedded interconnect structure formed by the set of sub-layer metal layers includes two metal layers. However, in other examples, the embedded interconnect structure includes more than two or fewer than two metal layers. The specific number of metal layers used in the embedded interconnect structure depends on factors such as the number of signal paths to be provided within the embedded interconnect structure, the line width and spacing of the metal lines in the embedded interconnect structure (which may depend on available process technologies, cost limitations, mechanical or thermal constraints, etc.), as well as other factors. When the embedded interconnect structure includes more than two metal layers, operations described with reference to Stages 2 and 3 above can be repeated to form additional metal layers. When the embedded interconnect structure includes a single metal layer, operations described with reference to Stage 3 can be omitted, and the fabrication operations can proceed from Stage 2 to Stage 4.

Stage 4 illustrates a state after a top dielectric layer 340 of the embedded interconnect structure has been formed over a top metal layer of the embedded interconnect structure (e.g., the metal layer 332 in FIG. 3A). In the example illustrated in FIG. 3A, the dielectric layer 340 is shown as applied to only one side of the embedded interconnect structure. For example, the metal layer 306 remains exposed on the side 330 of the set of primary metal layers 300. Optionally, in some implementations, a symmetric lamination process is used to apply the dielectric layer 340. In such implementations, one or more additional dielectric layers are coupled to the set of primary metal layers 300 on the side 330, as described with reference to the set of dielectric layers 210 of FIG. 2

Stage 5 illustrates a state after openings 350 and 352 are formed to provide access to the top metal layers of the embedded interconnect structure (e.g., the metal layer 332) and the set of primary metal layers 300 (e.g., the metal layer 302), respectively. For example, the openings can be formed using one or more processes, such as etching, drilling, ablation, etc.

Stage 6 of FIG. 3B illustrates a state after conductive vias (e.g., a conductive via 354) and metal lines and/or contact pads of a metal layer 358 are formed. In a particular implementation, formation of the conductive vias and the metal layer 358 is guided by a patterned layer 356. The patterned layer 356 includes a dry film layer or another mask layer (e.g., a photoresist layer) formed on the dielectric layer 340. The patterned layer 356 is patterned to include openings aligned with openings that expose the top layer of the set of primary metal layers 300 (e.g., the metal layer 302) and openings corresponding to metal lines and/or contact pads of the metal layer 358. The metal layer 358 and the conductive vias electrically connected to the primary metal layers 300 (e.g., a conductive via 354) can be formed using plating operations and/or deposition operations guided by the patterned layer 356.

The patterned layer 356 covers the openings (such as the opening 350) that expose the top metal layer of the embedded interconnect structure (e.g., the metal layer 332). Thus, formation of conductive vias that are electrically connected to the primary metal layers 300 is performed separately from formation of conductive vias that are electrically connected to the embedded interconnect structure.

Stage 7 illustrates a state after removal of the patterned layer 356. Removal of the patterned layer 356 exposes the openings 350 to provide access to portions of the metal layer 332. Removal of the patterned layer 356 can be performed using one or more stripping, delamination, or ashing operations, or other operations appropriate for separating the patterned layer 356 from adjoining structures, such as the metal layer 358 and/or the dielectric layer 340.

Stage 8 illustrates a state after formation and patterning of a patterned layer 362. The patterned layer 362 can include or correspond to a dry film or a curable resin. The patterned layer 362 is patterned to define openings 364 that expose the top metal layer of the embedded interconnect structure (e.g., the metal layer 332) and openings 366 that expose contact pads 360 of the primary metal layers 300 (e.g., contact pads of the metal layer 358).

Stage 9 illustrates a state after formation of bump pads 370 and bump pads 372 as guided by the patterned layer 362. The bump pads 370 are electrically connected to corresponding contact pads 360 of the primary metal layers 300 (e.g., contact pads of the metal layer 358). The bump pads 372 are electrically connected to the top metal layer of the embedded interconnect structure (e.g., the metal layer 332). Thus, the bump pads 370 have a different shape and size than the bump pads 372. For example, the bump pads 370 include or correspond to simple copper posts that extend upward (in the orientation illustrated in FIG. 3B) from underlying contact pads 360 of the metal layer 358. In contrast, each of the bump pads 372 includes a post portion 374 and a via portion 376. The via portion 376 extends through an opening (e.g., the opening 350) in the dielectric layer 340 to electrically connect to the top metal layer of the embedded interconnect structure (e.g., the metal layer 332), and the post portion 374 extends upward (in the orientation illustrated in FIG. 3B) from the corresponding via portion 376. Thus, an entire post structure from the top metal layer (e.g., metal layer 302) of the primary metal layers 300 to a top of one of the bump pads 370 includes two metal layers (i.e., is a two-layer post structure) including: a first layer including the conductive via 354 and a contact pad 360 of the metal layer 358 and a second layer corresponding to the bump pad 370 (e.g., a copper post deposited on a contact pad 360 of the metal layer 358). A post structure from the top metal layer (e.g., the metal layer 332) of the embedded interconnect structures to a top of one of the bump pads 372 is a single layer (i.e., is a one-layer post structure).

One challenge with forming bump pads 370, 372 having different shapes and sizes is aligning the upper portions of the bump pads 370, 372 to enable reliable die attach. In a particular implementation, this challenge is addressed by using a single metal deposition operation to form the bump pads 370 and the bump pads 372 concurrently, and designing the bump pads 370, 372 to have substantially equal three-dimensional volumes. In such implementations, the plating operation deposits copper (or some other metal or alloy) at each deposition location at approximately the same rate. Thus, the heights of the bump pads 370, 372 can be controlled by careful selection of other dimensions of the bump pads 370, 372 to ensure that the bump pads 370, 372 have the same volume at the endpoint of the plating operation.

Stage 10 of FIG. 3C illustrates a state after removal of the patterned layer 362. Removal of the patterned layer 362 exposes sides of the bump pads 370, upper portions of the bump pads 372 (e.g., post portions 374), sides of contact pads 360, an upper surface of the dielectric layer 340, or a combination thereof. Removal of the patterned layer 362 can be performed using one or more stripping, delamination, or ashing operations, or other operations appropriate for separating the patterned layer 362 from adjoining structures such as the metal layer 358, the bump pads 370, 372, and/or the dielectric layer 340.

Stage 11 illustrates a state after formation of a solder resist layer 368 covering the metal layer 358, the bump pads 370, 372, and the dielectric layer 340. The solder resist layer 368 can be formed using one or more lamination processes or one or more liquid or gel application processes (e.g., spraying, rolling, dipping, or other coating operations).

Stage 12 illustrates a state after thinning of the solder resist layer 368 to expose portions of the bump pads 370, 372. For example, the solder resist layer 368 can be thinned using one or more etch operations. In some implementations, the solder resist layer 368 is cured after thinning. In other implementations, the solder resist layer 368 is cured or partially cured before thinning (e.g., at Stage 11).

Stage 13 illustrates a state after dies 380 (including a die 380A and a die 380B) are attached to the bump pads 370 and 372 to form a device 390. In a particular implementation, the dies 380 include solder bumps 382, which are coupled to the bump pads 370, 372, and heated to reflow the solder bumps to electrically connect the dies 380 to the bump pads 370, 372. Electrically connecting the dies 380 to the bump pads 370 provides conductive paths between the dies 380 and off-package contacts. For example, electrically connecting the die 380A to a bump pad 370A provides a conductive path 388A from the die 380A to an off-package contact 374A, and electrically connecting the die 380B to a bump pad 370B provides a conductive path 388B from the die 380B to an off-package contact 374B. Electrically connecting the dies 380 to the bump pads 372 provides conductive paths between the dies 380. For example, electrically connecting the die 380A to a bump pad 372A and electrically connecting the die 380B to a bump pad 372B provides a conductive path 386 between the dies 380 through the embedded interconnect structure.

### Exemplary Flow Diagram of a Method for Fabricating a Device Including an Embedded Interconnect Structure

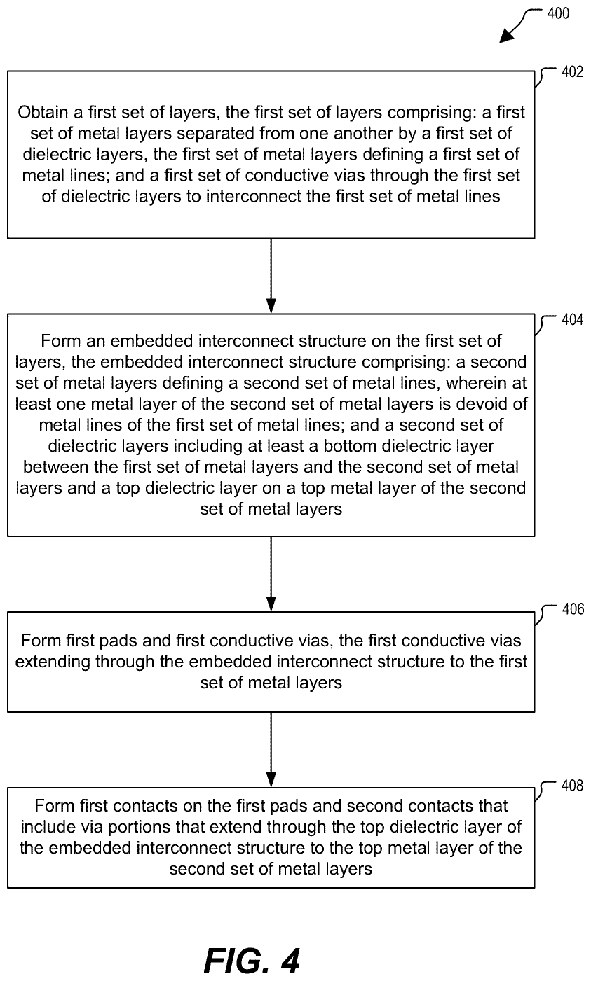

In some implementations, fabricating a device that includes an embedded interconnect structure includes several processes. FIG. 4 illustrates an exemplary flow diagram of a method 400 for providing or fabricating a device that includes an embedded interconnect structure. In some implementations, the method 400 of FIG. 400 may be used to provide or fabricate any of the device 100 of FIG. 1 or the device 390 of FIG. 3C. It should be noted that the method 400 of FIG. 4 may combine one or more processes in order to simplify and/or clarify the method for providing or fabricating an integrated device. In some implementations, the order of the processes may be changed or modified.

The method 400 includes, at block 402, obtaining a first set of layers. The first set of layers includes a first set of metal layers separated from one another by a first set of dielectric layers. The first set of metal layers defines a first set of metal lines. The first set of layers also includes a first set of conductive vias through the first set of dielectric layers to interconnect the first set of metal lines. For example, the first set of layers can include or correspond to the set of layers 208 of FIG. 2 or the set of primary metal layers 300 of FIG. 3A. The first set of layers can be obtained, for example, by laminating layers onto a core (e.g., the core 236 of FIG. 2) or onto a carrier substrate, patterning metal layers of the first set of layers to define metal lines, and forming conductive vias to interconnect various of the metal lines to define conductive paths through the first set of layers. In some instances, additional operations can be performed. To illustrate, one or more passive devices can be embedded within a core layer of the first set of layers and electrically connected to selected metal lines of the first set of metal lines.

The method 400 includes, at block 404, forming an embedded interconnect structure on the first set of layers. The embedded interconnect structure includes a second set of metal layers defining a second set of metal lines, and at least one metal layer of the second set of metal layers is devoid of metal lines of the first set of metal lines. The embedded interconnect structure also includes a second set of dielectric layers including at least a bottom dielectric layer between the first set of metal layers and the second set of metal layers and a top dielectric layer on a top metal layer of the second set of metal layers. For example, the embedded interconnect structure can include or correspond to features of the die-to-die interconnect region 130 of FIG. 1. To illustrate, the embedded interconnect structure can include the dielectric layer 144, the dielectric layer 170, the dielectric layer 172, the metal layer 146, the metal layer 148, and the conductive vias 168. As another example, the embedded interconnect structure can include or correspond to features of the set of layers 206 of FIG. 2. To illustrate, the embedded interconnect structure can include the dielectric layer 226, the metal layer 228, the dielectric layer 230, the metal layer 232, and the dielectric layer 234. In some implementations, the embedded interconnect structure is disposed within a die-to-die interconnect region, and no metal line of the first set of metal lines traverses the die-to-die interconnect region. For example, no metal line of the metal layer 112 traverses the die-to-die interconnect region 130 of FIG. 1. In some implementations, no metal line of the first set of metal lines is coplanar with any metal line of the second set of metal lines. For example, no metal line of the metal layer 112 is coplanar with any metal line of the metal layers 146, 148 of FIG. 1. Examples of operations that can be used to form the embedded interconnect structure are described with reference to Stages 2-4 of FIG. 3A.

The method 400 includes, at block 406, forming first pads and first conductive vias, where the first conductive vias extend through the embedded interconnect structure to the first set of metal layers. For example, the first pads and the first conductive vias can include or correspond to the post structure 126 of FIG. 1. Examples of operations that can be used to form the first pads and first conductive vias are described with reference to Stages 5-6 of FIGS. 3A-3C.

The method 400 includes, at block 408, forming first contacts on the first pads and second contacts that include via portions that extend through the top dielectric layer of the embedded interconnect structure to the top metal layer of the second set of metal layers. For example, the first contacts can include or correspond to the contacts 150 of FIG. 1, the contacts 222 of FIG. 2, or the bump pads 370 of FIG. 3B. The second contacts can include or correspond to, for example, the contacts 152 of FIG. 1, the contacts 220 of FIG. 2, or the bump pads 372 of FIG. 3B. Examples of operations that can be used to form the first and second contacts are described with reference to Stages 8-9 of FIG. 3B.

In some implementations, the method also includes electrically connecting a first die to a second die through the second contacts and the embedded interconnect structure. For example, the first and second dies can include or correspond to the dies 102 of FIG. 1 or the dies 380 of FIG. 3C. Examples of operations that can be used to electrically connect the first and second dies are described with reference to Stage 13 of FIG. 3C.

### Exemplary Electronic Devices

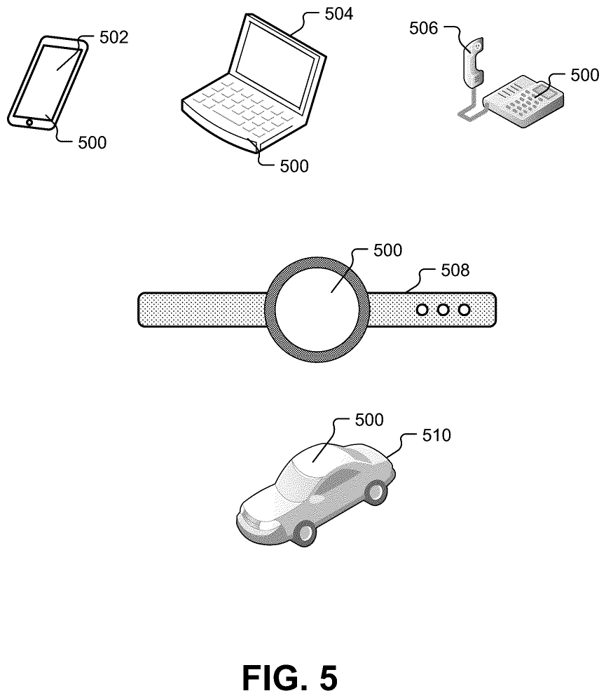

FIG. 5 illustrates various electronic devices that may include or be integrated with the device 100 of FIG. 1 or the device 390 of FIG. 3C. For example, a mobile phone device 502, a laptop computer device 504, a fixed location terminal device 506, a wearable device 508, or a vehicle 510 (e.g., an automobile or an aerial device) may include a device 500. The device 500 can include, for example, the device 100 of FIG. 1, the device 390 of FIG. 3C, or other devices described herein. The devices 502, 504, 506, and 508 and the vehicle 510 illustrated in FIG. 5 are merely exemplary. Other electronic devices may also feature the device 500 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1-5 may be rearranged and/or combined into a single component, process, feature or function or embodied in several components, processes, or functions. Additional elements, components, processes, and/or functions may also be added without departing from the disclosure. It should also be noted FIGS. 1-5 and its corresponding description in the present disclosure is not limited to dies and/or ICs. In some implementations, FIGS. 1-5 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes a substrate that includes first conductors electrically connecting first contacts on a first side of the substrate to second contacts on a second side of the substrate. The first conductors include a first set of metal lines arranged in a first set of metal layers separated from one another by a first set of dielectric layers. The first conductors also include a first set of conductive vias interconnecting the first set of metal lines through the first set of dielectric layers. The substrate also includes second conductors electrically connecting third contacts on the first side of the substrate to fourth contacts on the first side of the substrate to define conductive paths between a first die and a second die. The second conductors include a second set of metal lines arranged in a second set of metal layers that are separated from one another by a second set of dielectric layers. The second conductors also include a second set of conductive vias interconnecting the second set of metal lines. At least one metal layer of the second set of metal layers is devoid of metal lines of the first set of metal lines.

Example 2 includes the device of Example 1, wherein the first set of metal layers and the second set of metal layers are distinct and non-overlapping.

Example 3 includes the device of Example 1 or Example 2, wherein two or more dielectric layers of the second set of dielectric layers are disposed between the first side of the substrate and the first set of metal layers.

Example 4 includes the device of any of Examples 1 to 3, wherein a cross-section of a post structure of each of the first contacts is different from a cross-section of a post structure of each of the third contacts and each of the fourth contacts.

Example 5 includes the device of any of Examples 1 to 4 and further includes a two-layer post structure that includes one of the first contacts and a one-layer post structure that includes a via structure and one of the third contacts.

Example 6 includes the device of any of Examples 1 to 5 and further includes the first die coupled to the third contacts and to a first subset of the first contacts, and the second die coupled to the fourth contacts and to a second subset of the first contacts.

Example 7 includes the device of any of Examples 1 to 6, wherein the second set of conductors are disposed within a die-to-die interconnect region, and wherein no metal line of the first set of metal lines traverses the die-to-die interconnect region.

Example 8 includes the device of any of Examples 1 to 7, wherein no metal line of the first set of metal lines is coplanar with any metal line of the second set of metal lines.

Example 9 includes the device of any of Examples 1 to 8, wherein the first set of metal lines have first characteristic dimensions and the second set of metal lines have second characteristic dimensions, and wherein the first characteristic dimensions are greater than the second characteristic dimensions.

Example 10 includes the device of any of Examples 1 to 9, wherein the first set of metal lines have a first characteristic line width and the second set of metal lines have a second characteristic line width, and wherein the first characteristic line width is greater than the second characteristic line width.

Example 11 includes the device of any of Examples 1 to 10, wherein the first set of metal layers have a first characteristic layer thickness and the second set of metal layers have a second characteristic layer thickness, and wherein the first characteristic layer thickness is greater than the second characteristic layer thickness.

Example 12 includes the device of any of Examples 1 to 11, wherein the first set of dielectric layers have a first characteristic thickness and the second set of dielectric layers have a second characteristic thickness, and wherein the first characteristic thickness is greater than the second characteristic thickness.

Example 13 includes the device of any of Examples 1 to 12 and further includes a plurality of solder balls electrically connected to the second contacts to form a ball grid array.

According to Example 14, a device includes a first die comprising first circuitry, a second die comprising second circuitry, and a substrate. The substrate is configured to electrically connect the first circuitry to the second circuitry and to electrically connect the first circuitry, the second circuitry, or both, to one or more off-package devices. The substrate includes first conductors electrically connecting first contacts on a first side of the substrate to second contacts on a second side of the substrate. The first conductors include a first set of metal lines arranged in a first set of metal layers separated from one another by a first set of dielectric layers and a first set of conductive vias interconnecting the first set of metal lines through the first set of dielectric layers. The substrate also includes second conductors electrically connecting third contacts on the first side of the substrate to fourth contacts on the first side of the substrate to define conductive paths between the first die and the second die. The second conductors include a second set of metal lines arranged in a second set of metal layers that are separated from one another by a second set of dielectric layers and a second set of conductive vias interconnecting the second set of metal lines. At least one metal layer of the second set of metal layers is devoid of metal lines of the first set of metal lines.

Example 15 includes the device of Example 14, wherein the first set of metal layers and the second set of metal layers are distinct and non-overlapping.

Example 16 includes the device of Example 14 or Example 15, wherein two or more dielectric layers of the second set of dielectric layers are disposed between the first side of the substrate and the first set of metal layers.

Example 17 includes the device of any of Examples 14 to 16, wherein a cross-section of a post structure of each of the first contacts is different from a cross-section of a post structure of each of the third contacts and each of the fourth contacts.

Example 18 includes the device of any of Examples 14 to 17 and further includes a two-layer post structure that includes one of the first contacts and a one-layer post structure that includes a via structure and one of the third contacts.

Example 19 includes the device of any of Examples 14 to 18, wherein the second set of conductors are disposed within a die-to-die interconnect region, and wherein no metal line of the first set of metal lines traverses the die-to-die interconnect region.

Example 20 includes the device of any of Examples 14 to 19, wherein no metal line of the first set of metal lines is coplanar with any metal line of the second set of metal lines.

Example 21 includes the device of any of Examples 14 to 20, wherein the first set of metal lines have first characteristic dimensions and the second set of metal lines have second characteristic dimensions, and wherein the first characteristic dimensions are greater than the second characteristic dimensions.

Example 22 includes the device of any of Examples 14 to 21, wherein the first set of metal lines have a first characteristic line width and the second set of metal lines have a second characteristic line width, and wherein the first characteristic line width is greater than the second characteristic line width.

Example 23 includes the device of any of Examples 14 to 22, wherein the first set of metal layers have a first characteristic layer thickness and the second set of metal layers have a second characteristic layer thickness, and wherein the first characteristic layer thickness is greater than the second characteristic layer thickness.

Example 24 includes the device of any of Examples 14 to 23, wherein the first set of dielectric layers have a first characteristic thickness and the second set of dielectric layers have a second characteristic thickness, and wherein the first characteristic thickness is greater than the second characteristic thickness.

Example 25 includes the device of any of Examples 14 to 24 and further includes a plurality of solder balls electrically connected to the second contacts to form a ball grid array configured to be coupled to the one or more off-package devices.

Example 26 includes the device of any of Examples 14 to 25, wherein the first die is a first chiplet and the second die is a second chiplet designed to operate in conjunction with the first chiplet.

Example 27 includes the device of Example 26, wherein the first circuitry of the first chiplet includes one or more first functional circuit blocks and the second circuitry of the second chiplet includes one or more second functional circuit blocks, and wherein the one or more first functional circuit blocks and the one or more second functional circuit blocks are operationally dependent upon one another.

Example 28 includes the device of any of Examples 14 to 27, wherein the first circuitry of the first die defines one or more processor cores and the second circuitry of the second die defines one or more memory cells.

According to Example 29, a method of fabrication of a device includes obtaining a first set of layers. The first set of layers includes a first set of metal layers separated from one another by a first set of dielectric layers, the first set of metal layers defining a first set of metal lines. The first set of layers also includes a first set of conductive vias through the first set of dielectric layers to interconnect the first set of metal lines. The method also includes forming an embedded interconnect structure on the first set of layers. The embedded interconnect structure includes a second set of metal layers defining a second set of metal lines, where at least one metal layer of the second set of metal layers is devoid of metal lines of the first set of metal lines. The embedded interconnect structure includes a second set of dielectric layers including at least a bottom dielectric layer between the first set of metal layers and the second set of metal layers and a top dielectric layer on a top metal layer of the second set of metal layers. The method includes forming first pads and first conductive vias. The first conductive vias extend through the embedded interconnect structure to the first set of metal layers. The method includes forming first contacts on the first pads and second contacts that include via portions that extend through the top dielectric layer of the embedded interconnect structure to the top metal layer of the second set of metal layers.

Example 29 includes the method of Example 28 and further includes electrically connecting a first die to a second die through the second contacts and the embedded interconnect structure.

Example 30 includes the method of Example 28 or Example 29, wherein the embedded interconnect structure is disposed within a die-to-die interconnect region, and wherein no metal line of the first set of metal lines traverses the die-to-die interconnect region.

Example 31 includes the method of any of Examples 28 to 30, wherein no metal line of the first set of metal lines is coplanar with any metal line of the second set of metal lines.

Example 32 includes the method of any of Examples 28 to 31, wherein the first set of metal lines have first characteristic dimensions and the second set of metal lines have second characteristic dimensions, and wherein the first characteristic dimensions are greater than the second characteristic dimensions.

Example 33 includes the method of any of Examples 28 to 32, wherein the first set of metal lines have a first characteristic line width and the second set of metal lines have a second characteristic line width, and wherein the first characteristic line width is greater than the second characteristic line width.

Example 34 includes the method of any of Examples 28 to 33, wherein the first set of metal layers have a first characteristic layer thickness and the second set of metal layers have a second characteristic layer thickness, and wherein the first characteristic layer thickness is greater than the second characteristic layer thickness.

Example 35 includes the method of any of Examples 28 to 34, wherein the first set of dielectric layers have a first characteristic thickness and the second set of dielectric layers have a second characteristic thickness, and wherein the first characteristic thickness is greater than the second characteristic thickness.

Example 36 includes the method of any of Examples 28 to 35 and further includes forming a ball grid array on a side of the first set of layers opposite the first contacts, wherein the ball grid array is electrically connected, through the first set of metal lines, to the first contacts.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A device comprising:
a substrate comprising:
first conductors electrically connecting first contacts on a first side of the substrate to second contacts on a second side of the substrate, the first conductors including:
a first set of metal lines arranged in a first set of metal layers separated from one another by a first set of dielectric layers; and
a first set of conductive vias interconnecting the first set of metal lines through the first set of dielectric layers; and
second conductors electrically connecting third contacts on the first side of the substrate to fourth contacts on the first side of the substrate to define conductive paths between a first die and a second die, wherein the second conductors include:
a second set of metal lines arranged in a second set of metal layers that are separated from one another by a second set of dielectric layers; and
a second set of conductive vias interconnecting the second set of metal lines, and
wherein at least one metal layer of the second set of metal layers is devoid of metal lines of the first set of metal lines.

2. The device of claim 1, wherein the first set of metal layers and the second set of metal layers are distinct and non-overlapping.

3. The device of claim 1, wherein two or more dielectric layers of the second set of dielectric layers are disposed between the first side of the substrate and the first set of metal layers.

4. The device of claim 1, wherein a cross-section of a post structure of each of the first contacts is different from a cross-section of a post structure of each of the third contacts and each of the fourth contacts.

5. The device of claim 1, further comprising a two-layer post structure that includes one of the first contacts and a one-layer post structure that includes a via structure and one of the third contacts.

6. The device of claim 1, further comprising:
the first die coupled to the third contacts and to a first subset of the first contacts; and
the second die coupled to the fourth contacts and to a second subset of the first contacts.

7. The device of claim 1, wherein the second set of conductors are disposed within a die-to-die interconnect region, and wherein no metal line of the first set of metal lines traverses the die-to-die interconnect region.

8. The device of claim 1, wherein no metal line of the first set of metal lines is coplanar with any metal line of the second set of metal lines.

9. The device of claim 1, wherein the first set of metal lines have first characteristic dimensions and the second set of metal lines have second characteristic dimensions, and wherein the first characteristic dimensions are greater than the second characteristic dimensions.

10. The device of claim 1, wherein the first set of metal lines have a first characteristic line width and the second set of metal lines have a second characteristic line width, and wherein the first characteristic line width is greater than the second characteristic line width.

11. The device of claim 1, wherein the first set of metal layers have a first characteristic layer thickness and the second set of metal layers have a second characteristic layer thickness, and wherein the first characteristic layer thickness is greater than the second characteristic layer thickness.

12. The device of claim 1, wherein the first set of dielectric layers have a first characteristic thickness and the second set of dielectric layers have a second characteristic thickness, and wherein the first characteristic thickness is greater than the second characteristic thickness.

13. The device of claim 1, further comprising a plurality of solder balls electrically connected to the second contacts to form a ball grid array.

14. A device comprising:
a first die comprising first circuitry;
a second die comprising second circuitry; and
a substrate configured to electrically connect the first circuitry to the second circuitry and to electrically connect the first circuitry, the second circuitry, or both, to one or more off-package devices, the substrate comprising:
first conductors electrically connecting first contacts on a first side of the substrate to second contacts on a second side of the substrate, the first conductors including:
a first set of metal lines arranged in a first set of metal layers separated from one another by a first set of dielectric layers; and
a first set of conductive vias interconnecting the first set of metal lines through the first set of dielectric layers; and
second conductors electrically connecting third contacts on the first side of the substrate to fourth contacts on the first side of the substrate to define conductive paths between the first die and the second die, wherein the second conductors include:
a second set of metal lines arranged in a second set of metal layers that are separated from one another by a second set of dielectric layers; and
a second set of conductive vias interconnecting the second set of metal lines, and
wherein at least one metal layer of the second set of metal layers is devoid of metal lines of the first set of metal lines.

15. The device of claim 14, wherein the first set of metal layers and the second set of metal layers are distinct and non-overlapping.

16. The device of claim 14, wherein two or more dielectric layers of the second set of dielectric layers are disposed between the first side of the substrate and the first set of metal layers.

17. The device of claim 14, wherein a cross-section of a post structure of each of the first contacts is different from a cross-section of a post structure of each of the third contacts and each of the fourth contacts.

18. The device of claim 14, further comprising a two-layer post structure that includes one of the first contacts and a one-layer post structure that includes a via structure and one of the third contacts.

19. The device of claim 14, wherein the second set of conductors are disposed within a die-to-die interconnect region, and wherein no metal line of the first set of metal lines traverses the die-to-die interconnect region.

20. The device of claim 14, wherein no metal line of the first set of metal lines is coplanar with any metal line of the second set of metal lines.

21. The device of claim 14, wherein the first set of metal lines have first characteristic dimensions and the second set of metal lines have second characteristic dimensions, and wherein the first characteristic dimensions are greater than the second characteristic dimensions.

22. The device of claim 14, wherein the first set of metal lines have a first characteristic line width and the second set of metal lines have a second characteristic line width, and wherein the first characteristic line width is greater than the second characteristic line width.

23. The device of claim 14, wherein the first set of metal layers have a first characteristic layer thickness and the second set of metal layers have a second characteristic layer thickness, and wherein the first characteristic layer thickness is greater than the second characteristic layer thickness.

24. The device of claim 14, wherein the first set of dielectric layers have a first characteristic thickness and the second set of dielectric layers have a second characteristic thickness, and wherein the first characteristic thickness is greater than the second characteristic thickness.

25. The device of claim 14, further comprising a plurality of solder balls electrically connected to the second contacts to form a ball grid array configured to be coupled to the one or more off-package devices.

26. The device of claim 14, wherein the first die is a first chiplet and the second die is a second chiplet designed to operate in conjunction with the first chiplet.

27. The device of claim 26, wherein the first circuitry of the first chiplet includes one or more first functional circuit blocks and the second circuitry of the second chiplet includes one or more second functional circuit blocks, and wherein the one or more first functional circuit blocks and the one or more second functional circuit blocks are operationally dependent upon one another.

28. A method of fabrication, the method comprising:
obtaining a first set of layers, the first set of layers comprising:
a first set of metal layers separated from one another by a first set of dielectric layers, the first set of metal layers defining a first set of metal lines; and
a first set of conductive vias through the first set of dielectric layers to interconnect the first set of metal lines;
forming an embedded interconnect structure on the first set of layers, the embedded interconnect structure comprising:
a second set of metal layers defining a second set of metal lines, wherein at least one metal layer of the second set of metal layers is devoid of metal lines of the first set of metal lines; and
a second set of dielectric layers including at least a bottom dielectric layer between the first set of metal layers and the second set of metal layers and a top dielectric layer on a top metal layer of the second set of metal layers;
forming first pads and first conductive vias, the first conductive vias extending through the embedded interconnect structure to the first set of metal layers; and
forming first contacts on the first pads and second contacts that include via portions that extend through the top dielectric layer of the embedded interconnect structure to the top metal layer of the second set of metal layers.

29. The method of claim 28, further comprising electrically connecting a first die to a second die through the second contacts and the embedded interconnect structure.

30. The method of claim 28, wherein the embedded interconnect structure is disposed within a die-to-die interconnect region, and wherein no metal line of the first set of metal lines traverses the die-to-die interconnect region.
